(19) United States
(12) Patent Application Publication
(10) Pub. No.: US 2010/0289003 A1
(43) Pub. Date: Nov. 18, 2010

(54) MAKING COLLOIDAL TERNARY NANOCRYSTALS

(76) Inventors: Keith B. Kahen, Rochester, NY (US); Xiaofan Ren, Rochester, NY (US)

Correspondence Address: Patent Legal Staff;Eastman Kodak Company, 343 State Street, Rochester, NY, 14650-2201, US

(21) Appl. No.: 11/926,538

(22) Filed: Oct. 29, 2007

(51) Int. Cl. H01L 29/38; H01L 21/20

(52) U.S. Cl. 257/14; 438/478; 257/E21.09; 257/E29.105; 977/774

(57) ABSTRACT

A method of making a colloidal solution of ternary semiconductor nanocrystals, includes providing binary semiconductor cores; forming first shells on the binary semiconductor cores containing one of the components of the binary semiconductor cores and another component which when combined with the binary semiconductor will form a ternary semiconductor, thereby providing core/shell nanocrystals; and annealing the core/shell nanocrystals to form ternary semiconductor nanocrystals containing a gradient in alloy composition.

### CROSS-REFERENCE TO RELATED APPLICATIONS

Reference is made to commonly assigned U.S. patent application Ser. No. 11/226,622 filed Sep. 14, 2005, entitled “Quantum Dot Light Emitting Layer” by Keith B. Kahen; U.S. patent application Ser. No. 11/683,479 filed Mar. 8, 2007, entitled “Quantum Dot Light Emitting Device” by Keith B. Kahen; and U.S. patent application Ser. No. 11/770,8334 filed Jun. 29, 2007, entitled “Light-Emitting Nanocomposite Particles” by Keith B. Kahen, the disclosures of which are incorporated herein.

### STATEMENT REGARDING FEDERALLY-SPONSORED RESEARCH OR DEVELOPMENT

This invention was made with Government support under Cooperative Agreement #DE-FC26-06NT42864 awarded by DOE. The Government has certain rights in this invention.

### FIELD OF THE INVENTION

The present invention relates to making colloidal solutions of ternary nanocrystals.

### BACKGROUND OF THE INVENTION

Colloidal semiconductor nanocrystals, or quantum dots, have been the focus of a lot of research. Colloidal quantum dots, hereto within referred to as quantum dots or nanocrystals, are easier to manufacture in volume than self-assembled quantum dots. Colloidal quantum dots can be used in biological applications since they are dispersed in a solvent. Additionally, the potential for low cost deposition processes make colloidal quantum dots attractive for light emitting devices, such as LEDs, as well as other electronic devices, such as, solar cells, lasers, and quantum computing (cryptography) devices. While potentially broader in their applicability than self-assembled quantum dots, colloidal quantum dots do have some attributes that are comparatively lacking. For example, self-assembled quantum dots exhibit relatively short radiative lifetimes, on the order of 1 ns, while colloidal quantum dots typically have radiative lifetimes on the order of 20-200 ns. Individual colloidal quantum dots also exhibit blinking, characterized by a severe intermittency in emission, while self-assembled quantum dots do not have this characteristic.

Of particular interest are II-VI semiconductor nanocrystals. These nanocrystals have size-tunable luminescence emission spanning the entire visible spectrum. In photoluminescent applications, a single light source can be used for simultaneous excitation of different-sized dots, and their emission wavelength can be continuously tuned by changing the particle size. Since they are also able to be conjugated to biomolecules, such as, proteins or nucleic acids, this photoluminescence property makes them an attractive alternative for organic fluorescent dyes classically used in biomedical applications. Additionally, the tunable nature of the emission makes quantum dots well suited for full color display applications and lighting. As a result of their well-established high-temperature organometallic synthetic methods (Murray et al, J. Am. Chem. Soc. 115, 8706-8715 1993) and their size-tunable photoluminescence (PL) across the visible spectrum, CdSe nanocrystals have become the most extensively investigated quantum dots (QD).

As noted by Hohng et al (J. Am. Chem. Soc. 126 1324-1325 (2004)), colloidal semiconductor quantum dots are also brighter and far more photostable than organic dyes, making them particularly interesting for biological applications. It also has been reported in the open literature that surface passivation of quantum dots with a semiconductor layer having a wider band gap or with polymers improves the optical properties of quantum dots, such as, quantum yield and photobleaching. The blinking behavior of quantum dots, however, is generally considered an intrinsic limitation that is difficult to overcome. This is unfortunate because growing applications in spectroscopy of single biological molecules and quantum information processing using single-photon sources could greatly benefit from long-lasting and nonblinking single-molecule emitters. For instance, in a recent application of single-dot imaging, the tracking of membrane receptors was interrupted frequently due to the stroboscopic nature of recording. Blinking can also reduce the brightness in ensemble imaging via signal saturation.

A few groups have been working on solutions to the colloidal quantum dot blinking problem, especially for biological applications. It was found in 2004 by Hohng et al (Hohng et al., J. Am. Chem. So. 126, 1324-1325 (2004)) that quantum dot blinking could be suppressed by passivating the QD surface with thiol moieties. The experiments by Hohng et al were conducted with CdSe/ZnS quantum dots that showed inherent blinking behavior. Larson et al studied encapsulating the QDs within an amphiphilic polymer (Larson, et al., Science 300, 1434-1435, 2003), using water soluble CdSe/ZnS QDs. The results of Hohng et al and Larson et al do not solve the intrinsic problems resulting in blinking dots, they only control the environment at the surface of the dots in order to mitigate the problem. Both approaches are only useful in end applications that remain in solution and allow particular surface passivations.

In addition to the problem of blinking, colloidal quantum dots suffer from increased radiative lifetimes as compared with their self-assembled counterparts. Short radiative lifetimes are desirable in order to compete successfully with non-radiative recombination events, such as, Forster energy transfer and SRH recombination. Colloidal quantum dots with short radiative lifetimes would be advantaged as emitters in LEDs (both conventional and single photon), and phosphors for display and lighting applications.

With regard to conventional LEDs containing colloidal quantum dots, they have been incorporated in both inorganic and organic LED devices. To improve the performance of OLEDs, in the later 1990s OLED devices containing mixed emitters of organics and quantum dots were introduced (Matoussi et al., J. Appl. Phys. 83, 7965 (1998)). The virtue of adding quantum dots to the emitter layers is that the color gamut of the device could be enhanced; red, green, and blue emission could be obtained by simply varying the quantum dot particle size; and the manufacturing cost could be reduced. Because of problems, such as, aggregation of the quantum dots in the emitter layer, the efficiency of these devices was rather low in comparison with typical OLED devices. The efficiency was even poorer when a neat film of quantum dots was used as the emitter layer (Hikmet et al., J. Appl. Phys. 93, 3509 (2003)). The poor efficiency was attributed to the insulating nature of the quantum dot layer. Later the efficiency was boosted (to ˜1.5 cd/A) upon depositing a monolayer film of quantum dots between organic hole and electron transport layers (Coe et al., Nature 420, 800 (2002)). It was stated that luminescence from the quantum dots occurred mainly as a result of Forster energy transfer from excitons on the organic molecules (electron-hole recombination occurs on the organic molecules). Regardless of any future improvements in efficiency, these hybrid devices still suffer from all of the drawbacks associated with pure OLED devices.

Recently, a mainly all-inorganic LED was constructed (Mueller et al., Nano Letters 5, 1039 (2005)) by sandwiching a monolayer thick core/shell CdSe/ZnS quantum dot layer between vacuum deposited n- and p-GaN layers. The resulting device had a poor external quantum efficiency of 0.001 to 0.01%. Part of that problem could be associated with the organic ligands of trioctylphosphine oxide (TOPO) and trioctylphosphine (TOP) that were reported to be present post growth. These organic ligands are insulators and would result in poor electron and hole injection into the quantum dots. In addition, the remainder of the structure is costly to manufacture, due to the usage of electron and hole semiconducting layers grown by high vacuum techniques, and the usage of sapphire substrates.

The ability to generate single photons (using single photon LEDs) at a well-defined timing or clock is crucial for practical implementation of quantum key distribution (N. Gisin et al., Rev. Mod. Phys. 74, 145 (2002)), as well as for quantum computation (E. Knill et al., Nature 409, 46 (2001)) and networking based on photon qubits (quantum bits). Three different criteria are taken into account when evaluating the quality of a single photon source: high efficiency, small multiphoton probability (measured by the second order coherence function, g⁽²⁾(0)), and quantum indistinguishability. For some quantum cryptography implementations, such as, the BB84 protocol (N. Gisin et al., Rev. Mod. Phys. 74, 145 (2002), high efficiency and small g⁽²⁾(0) are required, but quantum indistinguishability is not necessary. On the other hand, for almost all other applications in quantum information systems, such as, linear optics quantum computation, LOQC (E. Knill et al., Nature 409, 46 (2001)), the photons need to undergo multiphoton interference, and as a result, quantum indistinguishability is required.

Single photon LEDs have been constructed that are optically pumped (C. Santori et al., Nature 419, 594 (2002)) and electrically pumped (Z. Yuan et al., Science 295, 102 (2002)), where in the majority of cases the emissive species has been self-assembled quantum dots. The typical way for improving the efficiency of the devices is to place the quantum dots within a microcavity configuration, where the best results are obtain for confinement in all three dimensions. As a result of the confinement, the IQE of the device is improved (due to the Purcell effect) and the collection efficiency is greatly enhanced (due to the large reduction in the number of available output modes). Associated with the improvement in the IQE is the large reduction in the quantum dot radiative lifetime (about a factor of 5), down to around 100-200 ps. This reduction in radiative lifetime also results in improvements in the quantum indistinguishability (A. J. Shields, Nature Photon. 1, 215 (2007)). Consequently, a key to both high efficiency and quantum indistinguishability is a short radiative lifetime. As such, forming colloidal quantum dots with this property would be highly desirable for quantum cryptography and quantum computing applications.

For solid-state lighting applications, the fastest route to high efficiency white LEDs is to combine either blue, violet, or near UV LEDs with appropriate phosphors. Replacing traditional optically pumped phosphors with quantum dot phosphors has many advantages, such as, greatly reduced scattering, ease of color tuning, improved color rendering index (CRI), lower cost deposition process, and broader wavelength spectrum for optical pumping. Despite these advantages, quantum dot phosphors have not been introduced into the marketplace due to some major shortcomings; such as, poor temperature stability and insufficient (10-30%) quantum yields for phosphor films with high quantum dot packing densities. In order to raise the quantum yield, many workers have lowered the packing density by incorporating appropriate filler (e.g., polymers or epoxies) with the quantum dots. The disadvantage of this approach is that the resulting quantum dot phosphor films are unacceptably thick (1 mm), as compared to the desired thickness of 10 μm. As has been discussed by Achermann et al (Achermann et el., Nano Lett 6, 1396 (2006)), reduced quantum yields for dense films is mainly the result of inter-nanoparticle interactions that lead to exciton transfer (Forster energy transfer) from emitting quantum dots to non-emitting quantum dots. Since the Forster energy transfer rate decreases rapidly with distance, d, as 1/d⁶, a way to minimize this effect is to form low-density films (with the aforementioned problems). A more desirable approach would be to decrease the radiative lifetime of the quantum dot emitters in order to compete more effectively with the Forster energy process, while enabling dense films of quantum dot phosphors. More specifically, the Forster energy transfer time for drop cast films of quantum dots has been experimentally measured to be on the nanosecond time scale (Achermann et al., J. Phys. Chem. B107, 13782 (2003)). In sum, forming colloidal quantum dot phosphors with improved temperature stability and short radiative lifetimes would remove two large hurdles currently preventing the widespread commercial usage of quantum dot phosphors for display and lighting applications.

Although quantum dots containing CdSe cores are arguably the most studied and best understood of the quantum dots, some researchers are looking at more complex quantum dots with ternary rather than binary compositions. U.S. Pat. No. 7,056,471 by Han et al discloses processes and uses of ternary and quaternary nanocrystals (quantum dots). The nanocrystals described by Han et al are not core/shell quantum dots, rather they are homogeneously alloyed nanocrystals (also referred to as nanoalloys). Although Han et al do not address the issue of blinking in their disclosure, Stefani et al use nanoalloy dots made by the disclosed process for a study of photoluminescence blinking (Stefani et al, New Journal of Physics 7, 197 (2005)). Stefani et al found that monocrystalline Zn_{0.42}Cd_{0.58}Se QDs with an average diameter of 6.2 nm exhibited photoluminescence blinking. Although Stefani et al do not discuss the radiative lifetimes of their ternary nanocrystals, Lee et al have studied colloidal ternary ZnCdSe semiconductor nanorods (Lee et al, Journal of Chemical Physics 125, 164711 (2006)). Lee et al found that the ternary nanorods exhibit radiative lifetimes slightly longer than comparable CdSe/ZnSe core/shell nanorods. The CdSe/ZnSe nanorods had lifetimes around 173 ns, while the shortest lifetime for the ternary rods was observed to be 277 ns.

To date, optoelectronic devices or biological (medical) studies have not had colloidal quantum dots (or nanocrystals) available that are inherently non-blinking or that have short radiative lifetimes. Previous methods to create non-blinking dots are application dependent and not universally applicable across the technical disciplines utilizing quantum dots. While self-assembled quantum dots exhibit short radiative lifetimes, there are no reports of colloidal quantum dots exhibiting similar performance. Therefore, there is a need for colloidal quantum dots with inherent non-blinking behavior for use in biological and optoelectronics applications. Additionally, there is a need for colloidal quantum dots with short radiative lifetimes that could be used in phosphor and optoelectronics applications.

### SUMMARY OF THE INVENTION

It is an object of this invention to provide an effective method of making colloidal solutions of ternary nanocrystals. This object is achieved by a method of making a colloidal solution of ternary semiconductor nanocrystals, comprising:

(a) providing binary semiconductor cores;

(b) forming first shells on the binary semiconductor cores containing one of the components of the binary semiconductor cores and another component which when combined with the binary semiconductor will form a ternary semiconductor, thereby providing core/shell nanocrystals; and

(c) annealing the core/shell nanocrystals to form ternary semiconductor nanocrystals containing a gradient in alloy composition.

It is another object of the present invention to provide improved ternary semiconductor nanocrystals. This object is achieved by a ternary semiconductor nanocrystal, comprising:

(a) a first lattice structure at the center of the nanocrystal and a second lattice structure different from the first lattice structure at the surface of the nanocrystal; and

(b) a lattice transition region formed between the nanocrystal center and the surface of the nanocrystal.

It is another object of the present invention to provide improved ternary semiconductor nanocrystals. This object is achieved by a ternary semiconductor nanocrystal, comprising:

(a) a ternary semiconductor having a first alloy composition at the center of the nanocrystal and a second alloy composition different from the first alloy composition at the surface of the nanocrystal;

(b) an alloy composition transition region formed between the nanocrystal center and the surface of the nanocrystal.

It is an advantage of the present invention that the colloidal ternary nanocrystals made in accordance with the present method exhibit the desirable properties of single molecule non-blinking (>1 minute), short radiative lifetimes (<10 ns), and stable fluorescence following high temperature anneals. It is an important feature of the invention that the ternary cores have a gradient in alloy composition in order to achieve the non-blinking and short radiative lifetime properties. Another advantage of the present invention is that colloidal ternary core/shell nanocrystals exhibiting these properties can be used to create advantaged quantum dot phosphors, medical and biological sensors, single photon LEDs, and high efficiency LEDs and lasers.

### BRIEF DESCRIPTION OF THE DRAWINGS

FIGS. 1A and 1B show schematics of one process of forming the inventive ternary nanocrystal with a gradient in its alloy composition;

FIG. 2 shows a schematic of a ternary core/shell nanocrystal of the present invention, wherein the ternary core has a gradient in its alloy composition;

FIG. 3 shows TEM data of ternary core/shell nanocrystals of the present invention;

FIG. 4 shows a STEM image of a ternary core/shell nanocrystal of the present invention;

FIGS. 5A and 5B show fluorescence time traces of the ternary core/shell nanocrystals of the present invention;

FIG. 6 shows the fluorescence time trace of a conventional nanocrystal representative of the prior art; and

FIGS. 7A and 7B shows the second-order correlation functions, g⁽²⁾(τ), for core/shell ternary nanocrystals of the present invention and for conventional prior art nanocrystals, respectively.

### DETAILED DESCRIPTION OF THE INVENTION

It is well known in the art that in order to reduce the deleterious effects of surface states on the optical and electrical properties of nanocrystals, it is advantageous to form nanocrystals with the smallest surface to volume ratio (thus, large nanoparticles). Taking the example of visible emitters and II-VI semiconductor nanocrystals, CdSe-based quantum dots can be used to generate red, green, and blue light. For the case of green emitters and CdSe nanocrystals, quantum size effects dictate the length scale of the quantum dots. A way to increase the size of the nanocrystal while maintaining the green emission is to add some Zn to the CdSe in order to increase the bandgap of the semiconductor material. The resulting material is the ternary alloy CdZnSe.

As discussed above in the background section, it is advantageous to create nanocrystals that don't blink and have short radiative lifetimes. Single molecule blinking is initiated (M. Nirmal et al., Nature 383, 802 (1996)) when a nanocrystal is excited by multiphotons and two or more electron-hole pairs are created. Instead of the energy being released radiatively, one of the pairs loses its energy by Auger recombination and transfers its energy to one of the remaining electrons or holes. The excited electron or hole can then be ejected from the nanocrystal into the surrounding matrix. In the resulting ionized nanocrystal, the Auger recombination process dominates over radiative recombination and the nanocrystal remains dark in spite of continual excitation. The nanocrystal will remain dark until the ejected carrier finds its way (via tunneling, for example) back into the nanocrystal and returns the nanocrystal to the uncharged state. As can be seen by this phenomenological model, blinking could be reduced or stopped by preventing the ejection of a carrier from the nanocrystal interior. Forming a very thick semiconductor shell (as for self-assembled quantum dots) is the straightforward solution, however, implementing this in practice is difficult since defect formation in the shell (due to lattice mismatch) scales with shell thickness. A nanocrystal with defects in its shell would not only blink (since charge can be trapped at the defects), but would also exhibit a reduced quantum efficiency. Thus, one needs to seek different ways for keeping the carriers confined within the nanocrystal volume and away from the surface. One can see that by engineering a nanocrystal where the electrons and holes are more tightly confined to the center region (and away from the surface), that this will also lead to a reduction in the electron and hole radiative lifetime as a result of the Purcell effect.

It is well known that as a result of Anderson localization (P. Anderson, Phys. Rev. 109, 1492 (1958)), even slight randomization of atomic positions (15%) or atomic energy levels will lead to localization of charge carriers in a material. Semiconductor substitutional alloys exhibit random variations in the atomic energy levels, and as such, manifest charge localization effects (E. Economou et al., Phys. Rev. Lett. 25, 520 (1970). Given this result, a hypothesized scenario for carrier localization in a nanocrystal would be to create a nanocrystal with an ordered core center, a random alloy middle shell, and an ordered outer shell. The ordered outer shell is added to ensure that the electron and holes remain confined to the core and middle shell regions. A way for creating this designer nanoparticle is discussed below.

Typically, ternary semiconductor alloy nanocrystals are created by adding, at the start of the synthesis, appropriate ratios of cations (e.g., CdZnSe) or anions (CdSeTe) into the synthesis reaction mixture (R. Bailey et al., JACS 125, 7100 (2003)). This procedure would normally result in an alloy homogenously distributed throughout the nanocrystal volume. Taking the example of the CdZnSe system, in order to form a random alloy middle shell, a more appropriate scheme would be to initially create a CdSe core, shell it with ZnSe, and then perform an appropriate anneal. As is well known in the art, the diffusion profile would be such that the maximum Zn concentration in the nanocrystal would occur at the surface, while in the core center the Zn content would be much lower (CdZnSe, but with a high Cd/Zn ratio). Given the weakening Zn penetration into the center of the nanocrystal, the surface region of the annealed nanoparticle would show the strongest random alloy attributes, with the core region behaving mainly as crystalline CdSe. As such, e-h pairs present in the core CdSe-like region would not only get localized by the increasing energy gap of the CdZnSe surface region, but also by carrier localization generated by the band of random alloy surrounding the core region of the nanocrystal. As stated above an extra outer shell of wide bandgap material, such as, ZnSeS or ZnS, could be added to the annealed nanostructure in order to ensure carrier confinement to the core and middle shell (containing the CdZnSe random alloy) regions.

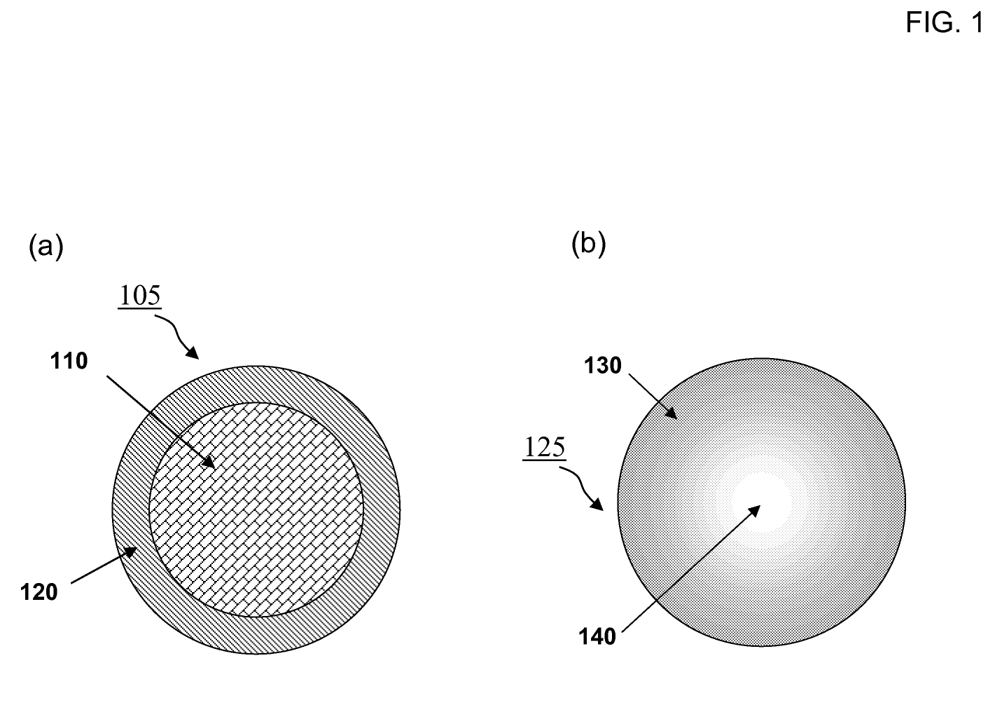

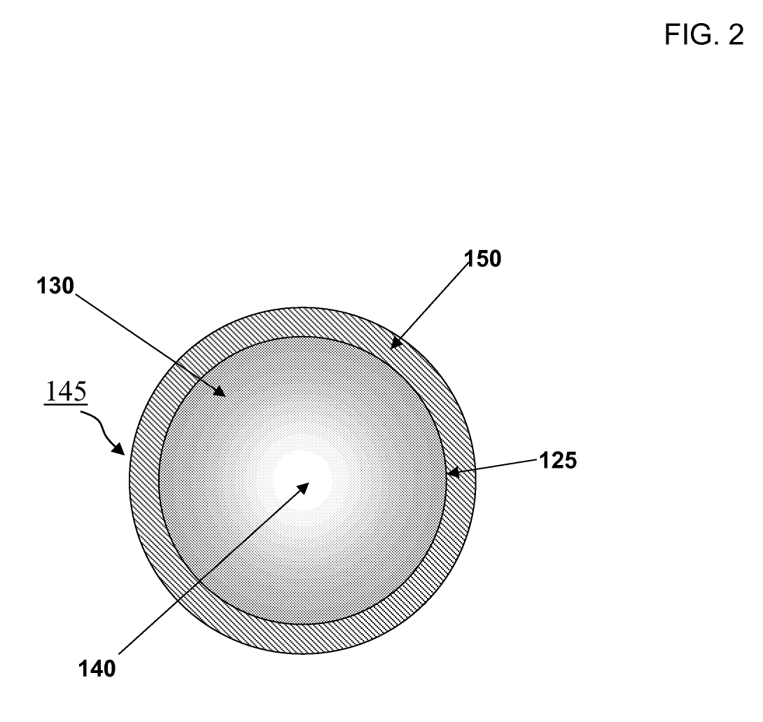

A more general description of the invented method of making colloidal ternary core/shell nanocrystals 145, whereby the ensuing nanocrystals demonstrate enhanced localization of the charge carriers to the center regions of the nanocrystals, is given below and illustrated in FIGS. 1 and 2. As a first step, a nanocrystal composed of a binary semiconductor needs to be synthesized by well-known procedures in the art. Typical synthetic routes include decomposition of molecular precursors at high temperatures in coordinating solvents (C. B. Murray et al., Annu Rev. Mater. Sci. 30, 545 (2000)), solvothermal methods (O. Masala and R. Seshadri, Annu Rev. Mater. Res. 34, 41 (2004)) and arrested precipitation (R. Rossetti et al., J. Chem. Phys. 80, 4464 (1984)). It is preferred that a binary semiconductor core 110 be composed of II-VI, III-V, or IV-VI semiconducting material. For the case of II-VI semiconductor material, preferred semiconductor binary compounds are CdSe, CdS, CdTe, ZnSe, ZnS, or ZnTe. Following the binary semiconductor core 110 synthesis, a first shell 120 is formed on the binary semiconductor core 110 by well-known procedures in the art. In order to form a ternary semiconductor nanocrystal 125, the first shell 120 needs to be composed of one of the components of the binary semiconductor core 110 and another component which when combined with the binary semiconductor core 110 will form a ternary semiconductor. The shelling is typically accomplished via the decomposition of molecular precursors at high temperatures in coordinating solvents (M. A. Hines et al., J. Phys. Chem. 100, 468 (1996)) or reverse micelle techniques (A. R. Kortan et al., J. Am. Chem. Soc. 112, 1327 (1990). Additional discussions of forming semiconducting shells on nanocrystal cores can be found in Masala (O. Masala and R. Seshadri, Annu Rev. Mater. Res. 34, 41 (2004)) and U.S. Pat. No. 6,322,901. The shell can be composed of II-VI, III-V, or IV-VI semiconducting materials. For the case of II-VI semiconductor material, preferred semiconductor binary compounds are CdSe, CdS, CdTe, ZnSe, ZnS, or ZnTe. Following the creation of core/shell nanocrystals 105, the core/shell nanocrystals 105 are annealed by well-know procedures in order to interdiffuse the core and shell semiconducting materials, resulting in the formation of a ternary semiconductor nanocrystal 125 with a gradient in its alloy composition. For a ternary alloy, interdiffusion will only occur on either the cation sublattice (e.g., CdZnSe) or the anion sublattice (e.g., CdSeTe). It is preferred that the annealing be performed between 250 and 350° C., with a preferred annealing time of 10 to 60 minutes. For example, as a result of the annealing of a CdSe/ZnSe core/shell nanocrystal 105, Zn diffuses into the CdSe binary semiconductor core 110 and creates a CdZnSe ternary semiconductor nanocrystal 125 with a gradient in Zn concentration. The thickness of the first shell 120 determines the alloy composition of the ternary semiconductor nanocrystal 125. For example, a core/shell nanocrystal 105 composed of CdSe/ZnSe with a thick ZnSe first shell 120 will result in a CdZnSe ternary semiconductor nanocrystal 125 with a correspondingly high Zn content.

Following the anneal step, a second shell 150 is grown on the ternary semiconductor nanocrystal 125. The shell is composed of a semiconducting material having an energy gap higher than that of a ternary surface region 130. Since shelling with III-V or IV-VI compounds remains problematic, it is preferred that a second shell 150 is composed of II-VI semiconducting material, with either a binary or a ternary composition. Examples are ZnS, ZnSe, ZnSeS, ZnSeTe, or ZnTeS. Formation of the second shell 150 is performed by well-known procedures in the art, such as, slowly adding molecular precursors to a solution containing the ternary semiconductor nanocrystals 125 in coordinating solvents. It should be noted that the second shell 150 could also be a multiple shell composite. Some possible examples are ZnSe/ZnSeS, ZnSeS/ZnS, and ZnSe/ZnSeS/ZnS.

After formation of the second shell 150, a second annealing step can be performed in order to examine the thermal stability of the as-prepared ternary core/shell nanocrystals 145. The annealing temperature is preferably between 300 and 350° C., with a preferred annealing time of 10 to 60 minutes. Following the anneal, temperature stable ternary core/shell nanocrystals 145 will only show small changes in their quantum yield and photoluminescence spectral response.

In the present invention, it is preferable that the cation used for synthesizing the ternary semiconductor nanocrystal 125 and its second shell 150 is a group IIb, IIIa or IVa material. Some examples of group IIb cation precursors are Cd(Me)₂, CdO, CdCO₃, Cd(Ac)₂, CdCl₂, Cd(NO₃)₂, CdSO₄, ZnO, ZnCO₃, Zn(Ac)₂, Zn(Et)₂, Hg₂O, HgCO₃ and Hg(Ac)₂. Some examples of group IIIa cation precursors are In(Ac)₃, InCl₃, In(acac)₃, In(Me)₃, h₂O₃, Ga(acac)₃, GaCl₃, Ga(Et)₃, and Ga(Me)₃. Other appropriate cation precursors can also be used as is well known in the art.

It is preferred that the anion precursor used for the synthesis of the ternary semiconductor nanocrystal 125 and its second shell 150 is a material selected from a group consisting of S, Se, Te, N, P, As, and Sb. Some examples of corresponding anion precursors are bis(trimethylsilyl)sulfide, tri-n-alkylphosphine sulfide, hydrogen sulfide, tri-n-alkenylphosphine sulfide, alkylamino sulfide, alkenylamino sulfide, tri-n-alkylphosphine selenide, alkenylamino selenide, tri-n-alkylamino selenide, tri-n-alkenylphosphine selenide, tri-n-alkylphosphine telluride, alkenylamino telluride, tri-n-alkylamino telluride, tri-n-alkenylphosphine telluride, tris(trimethylsilyl)phosphine, triethylphosphite, sodium phosphide, potassium phosphide, trimethylphosphine, tris(trimethylsilyl)arsenide, bis(trimethylsilyl)arsenide, sodium arsenide, and potassium arsenide. Other appropriate anion precursors can also be used as is well known in the art.

A wealth of suitable high boiling point compounds exist that can be used both as reaction media and, more importantly, as coordination ligands to stabilize the metal ion after it is formed from its precursor at high temperatures. They also aid in controlling particle growth and impart colloidal properties to the nanocrystals. Among the different types of coordination ligands that can be used are alkyl phosphine, alkyl phosphine oxide, alkyl phosphate, alkyl amine, alkyl phosphonic acid, and fatty acids. The alkyl chain of the coordination ligand is preferably a hydrocarbon chain of length greater than 4 carbon atoms and less than 30 carbon atoms, which can be saturated, unsaturated, or oligomeric in nature. It can also have aromatic groups in its structure.

Specific examples of suitable coordination ligands and ligand mixtures include, but are not limited to, trioctylphosphine, tributylphosphine, tri(dodecyl)phosphine, trioctylphosphine oxide, tributylphosphite, trioctyldecyl phosphate, trilauryl phosphate, tris(tridecyl)phosphate, triisodecyl phosphate, bis(2-ethylhexyl)phosphate, tris(tridecyl)phosphate, hexadecylamine, oleylamone, octadecylamine, bis(2-ethylhexyl)amine, octylaime, dioctylaime, cyclododecylamine, n, n-dimethyltetradecylamine, n, n-dimethyldodecylamine, phenylphosphonic acid, hexyl phosphonic acid, tetradecyl phosphonic acid, octylphosphonic acid, octadecyl phosphonic acid, propylphosphonic acid, aminohexyl phosphonic acid, oleic acid, stearic acid, myristic acid, palmitic acid, lauric acid, and decanoic acid.

Further, it can be used by diluting the coordinating ligand with at least one solvent selected from a group consisting of 1-nonadecene, 1-octadecene, cis-2-methyl-7-octadecene, 1-heptadecene, 1-pentadecene, 1-tetradecenedioctylether, dodecyl ether, hexadecyl ether or the like.

In order to enable the ternary core/shell nanocrystals 145 to be dispersed in various solvents, the nanocrystal surface needs to be functionalized with appropriate organic ligands. The procedure for exchanging the synthesis ligands with the appropriate surface functionalization ligands is well known in the art. For enabling the dispersion of the ternary core/shell nanocrystals 145 in various solvents, appropriate surface functionalization organic ligands can be represented by Xx(Y)nZz, wherein X is, for example, SH, NH₂, P, P═O, CSSH, or aromatic heterocycles; Z is, for example, OH, NH₂, NH₃⁺, COOH, or PO₃²⁻; and (Y)n is, for example, a material mainly having a structure of a saturated or unsaturated hydrocarbon chain, or an aryl that connects X and Y. It is preferable that a material is selected from a group consisting of pyridine, pyridine derivatives, mercapto-alkyl acid, mercapto-alkenyl acid, mercapto-alkyl amine, mercapto-alkenyl amine, mercapto-alkyl alcohol, mercapto-alkenyl alcohol, dihydrolipolic acid, alkylamino acid, alkenyl amino acid, aminoalkylcarboic acid, hydroxyalkylcarboic acid and hydroxyalkenylcarboic acid, but it is not limited to these materials as is well known in the art.

Although it is preferable that the size of the ternary core/shell nanocrystals 145 synthesized in accordance with the present invention is less than 20 nm, there is no limitation on the size thereof.

As discussed above with reference to the CdZnSe ternary semiconductor nanocrystal 125, the diffusion profile of Zn (from the ZnSe shell) would be such that the maximum Zn concentration in the nanocrystal would occur in the ternary surface region 130, while in the ternary center region 140 the Zn content would be much lower (CdZnSe, but with a high Cd/Zn ratio). As will be discussed in the example section below, an unexpected consequence of this profile (for the CdZnSe system) is that the underlying lattice structure changes from wurtzite in the ternary center region 140 to cubic (or zincblende) in the ternary surface region 130. Between the ternary center region 140 and ternary surface region 130, there is a lattice transition region where the lattice evolves from wurtzite to zincblende. One can account for this lattice structure evolution by noting that in the ternary center region 140 where the CdZnSe has a high Cd/Zn ratio, the lattice structure should reflect that of CdSe at room temperature, namely wurtzite. Correspondingly, in the ternary surface region 130, where the Cd/Zn ratio in CdZnSe is smaller than 1 (and possibly much smaller than 1), the lattice structure should reflect that of ZnSe at room temperature, namely zincblende. The physical consequence of the lattice structure change from ternary center region 140 to ternary surface region 130 is that it enhances the localization of the charge carriers to the ternary center region 140. Phenomenologically the added localization can be understood based on the following. Placing an electron in the wurtzite ternary center region 140, as it propagates outward in the core and begins to cross into the zincblende ternary surface region 130, the electron wave would scatter due to the change in the lattice structure (as stated above, even a small 15% random variation in lattice position causes Anderson localization). It should be noted that this extra confinement due to a change in lattice structure will only occur if the two binary components of the ternary alloy have different room temperature lattice structures. For the common II-VI binary compounds, CdSe and CdS form wurtzite nanocrystals, while CdTe, ZnS, ZnSe, and ZnTe form zincblende nanocrystals. Accordingly as examples, the ternary CdZnS would show a lattice change, while ZnSeTe would not. For the case of annealing CdTe/CdS core/shell nanocrystals 105, interdiffusion on the anion sublattice would be hypothesized to lead to a zincblende lattice in the ternary center region 140 and a wurtzite lattice in the ternary surface region 130. However, it has been noted previously (Zhong et al., JACS 125, 8589 (2003)) that interdiffusion on the anion sublattice occurs more slowly compared to that on the cation sublattice, as such, the annealing conditions would need to be adjusted to obtain a desired amount of interdiffusion.

Combining all of the above, confinement of the carriers in the ternary center region 140 of the invented ternary nanocrystal occurs as a result of three hypothesized phenomena brought on by the diffusion profile: 1) The energy gap of the ternary surface region 130 is larger than that of the ternary center region 140 (typical cause of confinement); 2) Anderson localization due to more significant random alloy formation in the ternary surface region 130 compared to that in the ternary center region 140; and 3) Scattering localization due to a difference in lattice structure between the ternary center region 140 (for example, wurtzite) and the ternary surface region 130 (for example, zincblende). In addition, after the annealing of the core/shell nanocrystal 105 to form a ternary semiconductor nanocrystal 125, one can add second shell(s) 150 to further confine the electrons and holes away from the ternary nanocrystal surface. As is well known in the art, the second shell(s) 150 will adopt the lattice structure of the ternary surface region 130.

A more general embodiment of the present invention is ternary semiconductor nanocrystals 125 that have a gradient in the alloy composition from the surface of the ternary nanocrystal to the center of the ternary nanocrystal. In the ternary center region 140 of the ternary semiconductor nanocrystal 125, the degree of alloying can be low such that the semiconductor material is largely binary in composition. Between the ternary center 140 and ternary surface 130 regions there is an alloy composition transition region where the alloy composition changes from its ternary center composition (mainly binary) to its ternary surface composition (ternary random alloy). To enable greater confinement of the electrons and holes, a shell (or multiple shells) can be added to the ternary semiconductor nanocrystals 125 (with a gradient in alloy composition) resulting in the formation of ternary core/shell nanocrystals 145. The ternary semiconductor nanocrystal (either core, core/shell, or core with multiple shells) can be a nanodot, a nanorod, a nanowire, a nano-tetrapod, or any other higher dimensional nanoscale particle that shows quantum confinement effects. With regard to material content, the ternary semiconductor nanocrystal 125 can include II-VI, III-V, or IV-VI semiconductive materials; some examples of ternary semiconductive materials are CdZnSe, CdZnS, InGaAs, and PbSeS, respectively. The second shell(s) 150 material of the ternary core/shell nanocrystals 145 can be composed of II-VI, III-V, or IV-VI semiconductive materials; however, it is preferred that the second shell 150 material be II-VI semiconductive material since, to date, successful nanocrystal shelling has only been performed with II-VI materials. The (multiple) second shell 150 material can either be a binary, ternary, or quaternary compound, for example, ZnSe, CdS, ZnS, ZnSeS, or CdZnSeS.

Another embodiment of the present invention is ternary semiconductor nanocrystals 125 that have a first lattice structure in their ternary center region 140 and a second lattice structure, different from the first lattice structure, in the ternary surface region 130. Between these ternary center 140 and surface 130 regions, there is a lattice transition region where the lattice evolves from the first lattice structure to the second lattice structure. One way of obtaining this lattice transformation of the ternary semiconductor nanocrystal 125 is to form the nanocrystal with a gradient in its alloy composition. Other ways of creating the lattice transformation are also possible as practiced in the art. Some examples of first and second lattice structures are wurtzite and zincblende, respectively, and the opposite combination of zincblende and wurtzite, respectively. To enable greater confinement of the electron and hole carriers, a second shell(s) 150 can be added to the ternary semiconductor nanocrystals 125 resulting in the formation of ternary core/shell nanocrystals 145. As discussed previously, the second shell 150 structure typically assumes the lattice structure of the ternary surface region 130 (second lattice structure). As an example, if the first and second lattice structures are wurtzite and zincblende, then the second shell 150 lattice structure is zincblende. The ternary semiconductor nanocrystal (either core, core/shell, or core with multiple shells) can be a nanodot, a nanorod, a nanowire, a nano-tetrapod, or any other higher dimensional nanoscale particle that shows quantum confinement effects. With regard to material content, the ternary semiconductor nanocrystal 125 can include II-VI, III-V, or IV-VI semiconductive materials; some examples of ternary semiconductive materials are CdZnSe, CdZnS, InGaAs, and PbSeS, respectively. The second shell(s) 150 material of the ternary core/shell nanocrystals 145 can be composed of II-VI, III-V, or IV-VI semiconductive materials; however, it is preferred that the second shell 150 material be II-VI semiconductive material since, to date, successful nanocrystal shelling has only been performed with II-VI materials. The (multiple) second shell 150 material can either be a binary, ternary, or quaternary compound, for example, ZnSe, CdS, ZnS, ZnSeS, or CdZnSeS.

The following examples are presented as further understandings of the present invention and are not to be construed as limitations thereon.

### Inventive Example I-1

### Preparation of the Inventive Ternary Core/Shell Non-Blinking Nanocrystals, CdₓZn₁₋ₓSe/ZnSe

All synthetic routes were carried out using standard airless procedures with a dry box and a Schlenk line. The first step in creating the ternary cores was to form CdSe cores. Typically, 0.0755 g of TDPA (1-tetradecylphosphonic acid), 4 g of pre-degassed TOPO (trioctylphosphine oxide), and 2.5 g of HDA (hexadecylamine) were added in a three-neck flask. The mixture was degassed at 100° C. for half an hour. The stock solution of 1 M TOPSe was prepared by dissolving of 0.01 mol selenium in 10 ml TOP (trioctylphosphine). 1 ml of TOPSe was added to the flask and the mixture was heated to 300° C. The cadmium stock solution (0.06 g of CdAc₂ in 3 ml TOP) was quickly injected under vigorous stirring resulting in nucleation of CdSe nanocrystals, after which time the temperature was set at 260° C. for further growth. After 5-10 min, the heating was removed and the flask was allowed to cool to room temperature.

2.5 ml of the as-prepared crude CdSe cores was reheated to 300° C. in half an hour. In a drybox, two solutions were prepared. One consisted of 0.14 ml of 1 M ZnEt₂ (in hexane) and 0.56 ml of TOP; the other consisted of 0.14 ml of 1 M TOPSe (in TOP) and 0.56 ml of additional TOP. Both solutions were loaded into a 1 ml syringe respectively. As soon as the temperature of the core crude solution reached 300° C., 0.35 ml of the ZnEt₂ solution was injected from the syringe into the heated solution, followed by the injection of 0.35 ml TOPSe solution in 20 seconds. The above procedure was repeated at time intervals of 20 seconds till the contents of both syringes were emptied. After the addition, the reaction mixture was heated for 5 more minutes, and then heat was removed to stop the reaction.

The final step in the process was shelling of the CdZnSe ternary cores. A three-neck reaction flask with as-prepared crude CdₓZn₁₋ₓSe cores was heated to 190° C. The solution of ZnEt₂ (1 M, 0.625 ml) and TOPSe (1M, 1.25 ml) in 1 ml TOP was slowly added dropwise under vigorous stirring. After the addition the temperature was lowered to 180° C. and the solution was left to stir for another hour to form annealed CdₓZn₁₋ₓSe/ZnSe nanocrystals.

### Inventive Example I-2

### Preparation of the Inventive Ternary Core/Shell Non-Blinking Nanocrystals, CdₓZn₁₋ₓSe/ZnSeS

All synthetic routes were carried out using standard airless procedures with a dry box and a Schlenk line. The first step in creating the ternary cores was to form CdSe cores. In a three-neck flask, 0.2 mmol of CdO and 0.5 g of stearic acid were heated to 180° C. until the mixture went clear. Inside of a dry box, 3 ml of HDA and 6 ml of TOPO were added to the mixture. On a Schlenk line the mixture was heated to 310° C. under vigorous stirring, whereupon 1 ml of 1 M TOPSe was injected. The temperature was then lowered to 290-300° C. and stirred for an additional 10 minutes.

Next a ZnSe shell was formed on the CdSe cores. After cooling the core crude solution back to room temperature, it was reheated to 190° C. In a syringe was added 260 μl of 1M diethylzinc in hexane, 260 μl of 1M TOPSe, and 2 ml of TOP. The contents of the syringe were then added to the CdSe core crude solution at a rate of 10 ml/hr. After the addition the mixture temperature was lowered to 180° C., in order to anneal the resulting ternary cores for 45-90 minutes. After the 180° C. anneal, the mixture temperature was taken back to room temperature. A second anneal was then performed for 30 minutes at 300° C. to create the ternary core nanocrystals containing a gradient in the alloy composition.

The final step in the process was shelling of the CdZnSe ternary cores with ZnSeS (ZnSe_{0.33}S_{0.67} in the example below). In a new 3-neck flask was added 1.5 ml of the CdZnSe crude cores, 4 ml of TOPO, and 3 ml of HDA, followed by heating the mixture to 190° C. In a syringe was added 804 μl of 1 M diethylzinc in hexane, 268 μl of 1M TOPSe, 536 μl of 0.25M bis(trimethylsilyl)sulfide in hexane, and 2.5 ml of TOP. The contents of the syringe were then added to the CdZnSe core crude solution at a rate of 10 ml/hr. After the addition the mixture temperature was lowered to 180° C., in order to anneal the resulting ternary cores for 45-90 minutes.

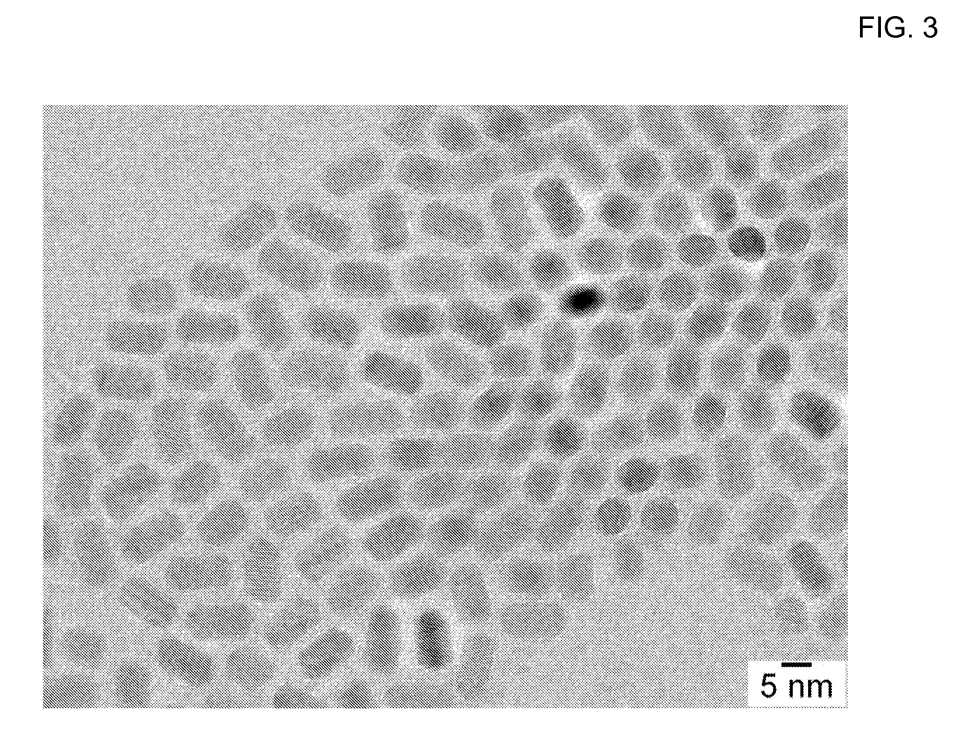

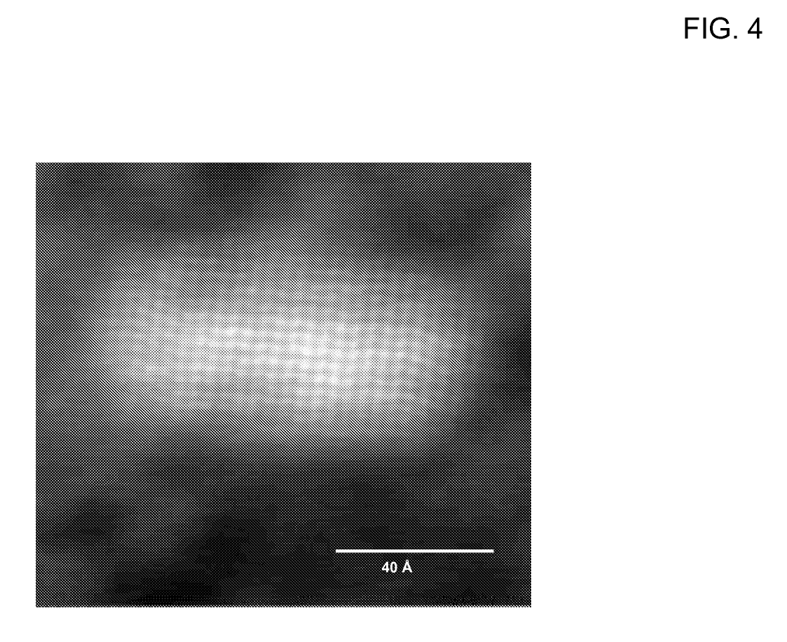

FIG. 3 shows a TEM (transmission electron microscopy) image of the core/shell ternary nanocrystals of this example. It should be noted that the emissive nanocrystals were quantum rods with an aspect ratio of approximately 2.5:1. FIG. 4 shows a STEM (scanning TEM) image of an isolated ternary core/shell nanocrystal of this example. The image was taken at a magnification of 5 million. The nanocrystal was imaged along the (−2 1 0 0) wurtzite axis. The image shows that the nanocrystal has a wurtzite lattice structure in the center of the nanorod (as evidenced by the waviness of the lattice fringes) and at the ends of the nanorod has a cubic (or zincblende) lattice as evidenced by the alignment of the lattice fringes. STEM images showing the lattice transition from wurtzite at the center of the nanocrystal to cubic (zincblende) at the surface of the nanocrystal were also obtained for core ternary nanocrystals (thus without a outer shell) of this example.

### Single Molecule Blinking and Anti-Bunching Measurements

Standard single molecule blinking and anti-bunching measurements were performed on the ternary core/shell nanocrystals of examples I-1 and I-2. In addition for comparison, prior art CdTe nanocrystals (80% quantum yield) from Quantum Dot Corporation were also measured. For both single molecule measurements, standard procedures were followed for creating very dilute films of the nanocrystals on quartz coverslips. The optical measurements were made using a Nikon confocal microscope excited by a 532 nm continuous green laser. The laser excitation was focused to a diffraction limited spot of ˜400 nm by an oil immersion objective (1.5 NA). The emission from the sample was collected through the same objective, with the 532 nm light rejected by a filter. The emission was then directed into a silicon avalanche photodiode (SAPD). The fluorescence intensity versus time trace was obtained by feeding the SAPD output into a TTL multichannel scaler with integration times of 1-30 ms/bin. The laser power density used to excite all of the nanocrystals (both inventive and prior art) was varied from ˜0.1-10 kW/cm². The anti-bunching measurements were performed using a Hanbury-Brown and Twiss setup (R. Hanbury et al., Nature 177, 27 (1956)) with a 50/50 beamsplitter and two single-photon counting SAPDs. The two SAPDs were connected to the start and stop inputs of a time-to-amplitude converter, whose output was stored in a time correlated photon counting card.

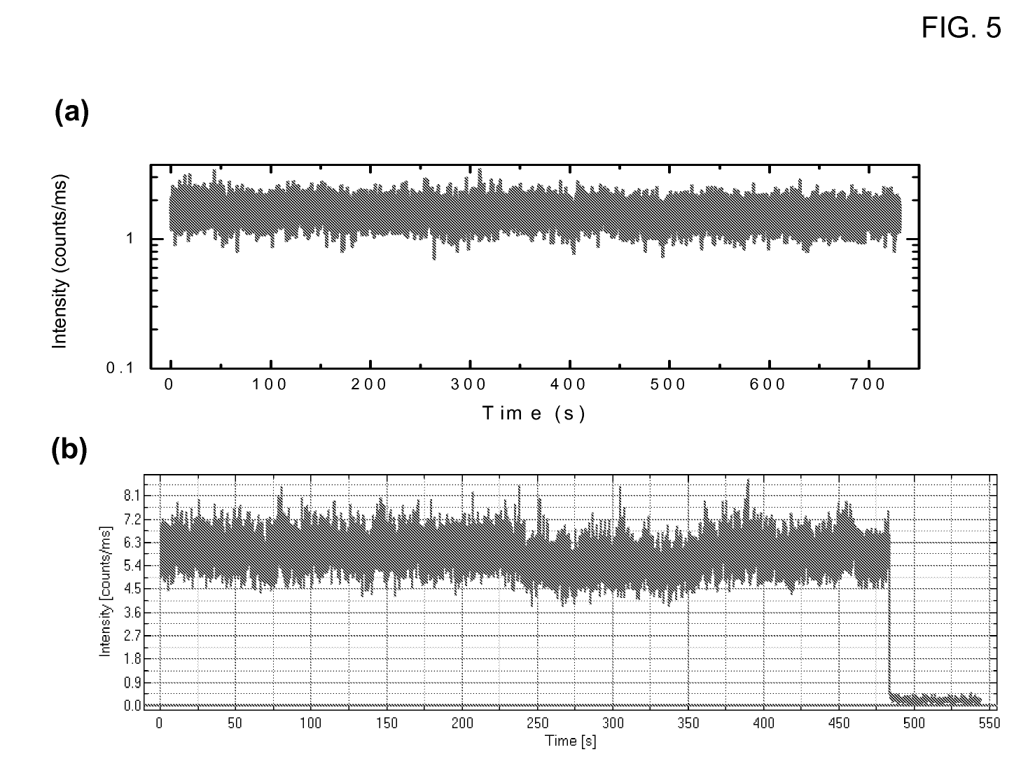

FIGS. 5A and 5B give examples of the fluorescence time traces for the core/shell ternary nanocrystals of example I-1. For the data shown in FIG. 5A the laser power density was ˜1 kW/cm² (30 ms time bins), while for the data of FIG. 5B, the laser power density was ˜10 kW/cm² (10 ms time bins). As can be seen, the ternary nanocrystals have on-times of ˜10 minutes. In fact, the ternary nanocrystals turn off not due to blinking phenomena, but due to being photo-bleached. As a result the ternary nanocrystals with good photostability characteristics had on times up to several hours (for the 1 kW/cm² excitation density). It was also verified that blinking did not occur on a very fast time scale, since similar time traces were obtained for time bins as small as 1 ms. At the higher laser power excitation density of 10 kW/cm², FIG. 5B shows that the ternary dots can have on-times of ˜10 minutes (beyond ˜10 minutes, all of the ternary dots become photo-bleached at the 10 kW/cm² excitation density). The ternary dots from example I-2 also had very long on-times (>10 minutes); in addition they turned off as a result of being photo-bleached.

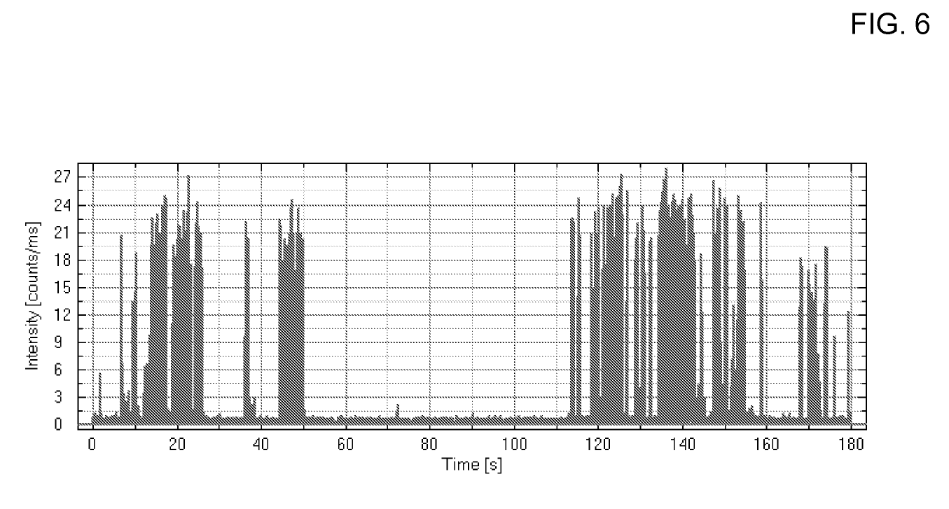

For comparison FIG. 6 shows the fluorescence time trace of the prior art CdTe nanocrystals at a laser power excitation density of 10 kW/cm², where the collection times bins were 10 ms. The time trace behavior shown in FIG. 6 is typical of nanocrystals films reported in the literature, where the highest reported on-times are ˜1 minute. As such, the inventive ternary core/shell nanocrystals have significantly different single molecule fluorescence intermittency behavior compared to prior art nanocrystals previously reported in the literature.

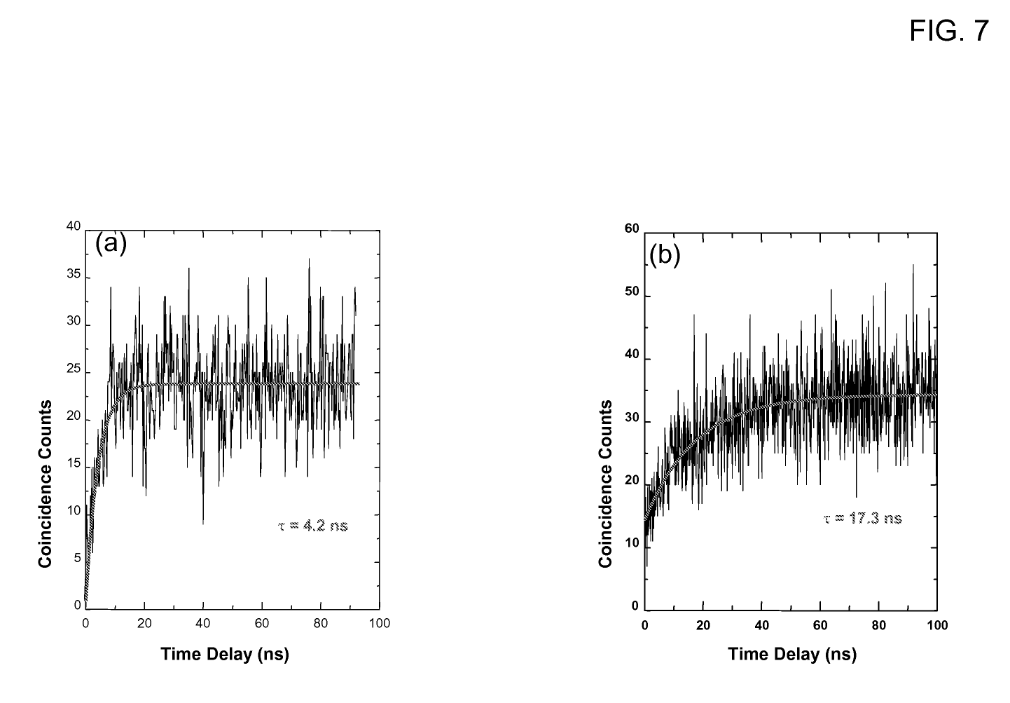

FIGS. 7A and 7B give representative second-order correlation functions, g⁽²⁾(τ) for the core/shell ternary nanocrystals of example I-1 and the prior art CdTe nanocrystals, respectively. The correlation function for the ternary nanocrystals shows unambiguous anti-bunching behavior at τ=0. This is especially important for the inventive nanocrystals since it demonstrates that the non-blinking behavior is due to isolated nanocrystals. As can be seen the radiative lifetime of the core/shell ternary nanocrystals (4-5 ns, on average) was significantly lower than that for the prior art CdTe nanocrystals (20 ns on average). For comparison, radiative lifetimes (derived by anti-bunching measurements) for quantum rods can range from 20-200 ns, while lifetimes for self-assembled quantum dots are in the 1-2 ns range. For the ternary core/shell nanocrystals of example 1-2, photo-bleaching issues led to difficulties in extracting a radiative lifetime using anti-bunching measurements.

### Quantum Yield Measurements

Absolute quantum yield measurements (using an integrating sphere) were made for dense nanocrystal films composed of the core/shell ternary nanocrystals from examples I-1 and I-2. For the I-1 case, a standard ligand exchange was performed to remove the TOPO, HDA, and TOP ligands and replace them solely with HDA. Concentrated dispersions of the HDA terminated nanocrystals were drop cast out of toluene onto glass slides. The resulting absolute quantum yield was ˜75%. In comparison the relative quantum yield of the corresponding dispersion was ˜80%. For the 1-2 case, a ligand exchange was performed to replace the growth ligands with pyridine. Once more a concentrated dispersion was formed (ethanol solvent) and drop cast onto glass slides. The resulting absolute quantum yields of the films were ˜40%, while that for the corresponding dispersion was ˜36%. In both cases, there is no degradation (within experimental error) in quantum yield in going from solution measurements to dense film measurements. In comparison, it is well known that typical nanocrystals suffer at least a factor of 2 or 3 drop-off in quantum yield in going from solution to film (Achermann et al., Nano Lett 6, 1396 (2006)).

In summary, the core/shell ternary nanocrystals of examples I-1 and I-2 exhibit no blinking (with on times greater than hours), very short radiative lifetimes (4-5 ns) that are reminiscent of self-assembled quantum dots, and resistance to proximity quenching in dense nanocrystal phosphor films.

The invention has been described in detail with particular reference to certain preferred embodiments thereof, but it will be understood that variations and modifications can be effected within the spirit and scope of the invention.

### PARTS LIST

105 core/shell nanocrystal
110 binary semiconductor core
120 first shell
125 ternary semiconductor nanocrystal
130 ternary surface region
140 ternary center region
145 ternary core/shell nanocrystal
150 second shell

1. A method of making a colloidal solution of ternary semiconductor nanocrystals, comprising:
(a) providing binary semiconductor cores;
(b) forming first shells on the binary semiconductor cores containing one of the components of the binary semiconductor cores and another component which when combined with the binary semiconductor will form a ternary semiconductor, thereby providing core/shell nanocrystals; and
(c) annealing the core/shell nanocrystals to form ternary semiconductor nanocrystals containing a gradient in alloy composition.

2. The method of claim 1 further comprising forming ternary core/shell nanocrystals by forming second shells on the ternary semiconductor nanocrystals.

3. The method of claim 1 wherein the binary semiconductor cores include II-VI, III-V, or IV-VI semiconductor materials.

4. The method of claim 3 wherein the II-VI semiconductor material includes CdSe, CdS, CdTe, ZnSe, ZnS, or ZnTe.

5. The method of claim 1 wherein the first shells include II-VI, III-V, or IV-VI semiconductor materials.

6. The method of claim 5 wherein the II-VI semiconductor material includes CdSe, CdS, CdTe, ZnSe, ZnS, or ZnTe.

7. The method of claim 2 wherein the second shells include binary or ternary II-VI, III-V, or IV-VI semiconductor materials.

8. The method of claim 7 wherein the binary or ternary II-VI semiconductor material includes ZnS, ZnSe, ZnSeS, ZnSeTe, or ZnTeS.

9. The method of claim 1 wherein the annealing occurs at a temperature between 250° C. and 350° C.

10. The method of claim 1 wherein the annealing time is 10 to 60 minutes.

11. The method of claim 2 further comprising a second anneal after the formation of the second shell.

12. The method of claim 1 wherein the ternary semiconductor nanocrystals have lattice structures that vary from wurtzite at the center to zincblende at the surface.

13. The method of claim 12 wherein the ternary semiconductor nanocrystals have second shells that have a zincblende lattice structure.

14. A ternary semiconductor nanocrystal, comprising:
(a) a first lattice structure at the center of the nanocrystal and a second lattice structure different from the first lattice structure at the surface of the nanocrystal; and
(b) a lattice transition region formed between the nanocrystal center and the surface of the nanocrystal.

15. The ternary semiconductor nanocrystal of claim 14 further comprising shell(s) formed on the ternary semiconductor nanocrystal having the second lattice structure.

16. The ternary semiconductor nanocrystal of claim 14 wherein the ternary semiconductor nanocrystal has a lattice structure that varies from wurtzite at the center to zincblende at the nanocrystal surface.

17. The ternary semiconductor nanocrystals of claim 16 further comprising shell(s) having a zincblende lattice structure.

18. The ternary semiconductor nanocrystal of claim 14 wherein the ternary semiconductor nanocrystal includes II-VI, III-V, or IV-VI semiconductor material.

19. A ternary semiconductor nanocrystal, comprising:
(a) a ternary semiconductor having a first alloy composition at the center of the nanocrystal and a second alloy composition different from the first alloy composition at the surface of the nanocrystal;
(b) an alloy composition transition region formed between the nanocrystal center and the surface of the nanocrystal.

20. The ternary semiconductor nanocrystal of claim 19 further comprising shell(s) formed on the ternary semiconductor nanocrystal.

21. The ternary semiconductor nanocrystal of claim 19 wherein the ternary semiconductor nanocrystal includes II-VI, III-V, or IV-VI semiconductor material.

22. The ternary semiconductor nanocrystal of claim 21 wherein the semiconductor material includes CdZnSe, CdZnS, InGaAs, or PbSeS.

23. The ternary semiconductor nanocrystal of claim 20 wherein the shell(s) includes II-VI, III-V, or IV-VI semiconductor material.

24. The ternary semiconductor nanocrystal of claim 23 wherein the shell is ZnSe, ZnSeS, or ZnSeS/ZnS.
